(19) United States
(12) Patent Application Publication
(10) Pub. No.: US 2025/0349767 A1
(43) Pub. Date: Nov. 13, 2025

(54) SEMICONDUCTOR PACKAGE STRUCTURE WITH IMPROVED DIE PAD AND METHOD THEREOF

(71) Applicant: WALTON ADVANCED ENGINEERING INC., Kaohsiung (TW)

(72) Inventors: Hong Chi YU, Kaohsiung (TW); Chun Jung LIN, Kaohsiung (TW); Ruei Ting GU, Kaohsiung (TW)

(21) Appl. No.: 18/950,904

(22) Filed: Nov. 18, 2024

(30) Foreign Application Priority Data
May 8, 2024 (TW) 113116962

(51) Int. Cl. H01L 23/00

(52) U.S. Cl. CPC H01L 24/05; H01L 24/03; H01L 24/04; H01L 24/16; H01L 24/24; H01L 24/48; H01L 2224/03416; H01L 2224/03452; H01L 2224/03462; H01L 2224/0361; H01L 2224/0362; H01L 2224/039; H01L 2224/04073; H01L 2224/05022; H01L 2224/05073; H01L 2224/05124; H01L 2224/05562; H01L 2224/05564; H01L 2224/05568; H01L 2224/05578; H01L 2224/05582; H01L 2224/05624; H01L 2224/05644; H01L 2224/05655; H01L 2224/16227; H01L 2224/24225; H01L 2224/48227; H01L 2924/35; H01L 2924/365

(57) ABSTRACT

The present invention introduces a semiconductor package structure with an enhanced die pad and its manufacturing method, designed to improve electrical connection performance and stability between the chip and carrier board. The structure comprises a chip unit featuring at least one die pad, each with a bonding area and a surrounding peripheral area. A key innovation is the direct application of a nickel-gold layer over the die pad, which optimizes electrical connections and offers superior oxidation protection, thereby extending the package's lifespan. To ensure stable electrical connections, the invention utilizes connection technologies such as wire bonding, Redistribution Layer (RDL), or direct soldering. These advanced methods enhance reliability and performance under demanding conditions. Overall, this invention provides a high-performance, high-reliability chip packaging solution by combining the nickel-gold die pad coverage with sophisticated connection techniques, significantly improving protection against environmental factors and meeting the stringent requirements of modern electronic devices.

### BACKGROUND OF THE INVENTION

### Field of the Invention

The present invention belongs to the technical field of semiconductor packaging, focusing on the improvement of chip packaging structures and their manufacturing methods. It aims to enhance the electrical connection performance and stability between the chip and the carrier board. This technology involves directly covering the die pad on the chip unit with a nickel-gold layer to optimize electrical connections and provide excellent oxidation protection, thereby extending the packaging lifespan. Innovations include the nickel-gold layer coverage over the bonding area of the die pad, combined with advanced connection technologies such as wire bonding, Redistribution Layer (RDL), or direct soldering. These improvements not only enhance connection reliability but also strengthen overall protection against environmental factors, meeting the stringent requirements of modern high-performance electronic devices.

### Description of the Prior Art

The semiconductor packaging technology field has made significant progress over the past few decades. Traditional chip packaging techniques primarily focus on effectively connecting the chip to the carrier board while protecting the chip from physical damage and environmental impact. In these techniques, chips are typically connected to external circuits through die pads (PADS), and the design and material selection of these die pads are crucial to the performance of the entire package.

However, as electronic devices advance towards higher performance, smaller sizes, and longer lifespans, existing packaging technologies face new challenges. Specifically, in terms of electrical connection stability, oxidation protection, and overall reliability of the package, traditional die pad coverage materials and connection methods struggle to meet the increasingly stringent technical requirements. For example, ordinary metal coverage layers, while providing basic electrical connections, are prone to oxidation when exposed to harsh environments for long periods, leading to connection failures. Additionally, traditional connection technologies such as soldering or wire bonding, although widely used, may not provide the necessary performance and reliability for high-density packaging or high-frequency applications.

Therefore, there is an urgent need for a new chip packaging structure and manufacturing method that can provide superior electrical connection performance and stability while enhancing chip protection, particularly against oxidation, to support the demands of modern high-performance electronic devices.

Relevant literature on die pads includes multiple patents as follows:

R.O.C. Patent 111135356 discloses a chip packaging structure with a protective layer on the die pad, where at least one protective layer is covered on the peripheral area of at least one die pad to reduce the exposed area of each die pad and shield the peripheral area of each die pad. The protective layer does not cover the bonding area of each die pad, exposing the bonding area to the outside. In a cross-line state, any solder wire cross-positioned between any die pad and its corresponding connection pad on the carrier board is not cross-positioned in the second upper space defined by the bonding area of other die pads. This isolates any solder wire cross-positioned between any die pad and its corresponding connection pad from the peripheral areas of other die pads by the protective layer on the peripheral areas, increasing the product's market competitiveness.

R.O.C. Patent 1671534 discloses a method for testing a semiconductor die. The method includes the following steps: charging a die pad of the semiconductor die to a pre-charge level; stopping the charging of the die pad to detect the time period required for the voltage level of the die pad to change from the pre-charge level to a reference level, and generating a detection result accordingly; and determining the leakage current of the die pad based on the detection result.

U.S. Pat. No. 9,691,686B2 discloses an embodiment providing a semiconductor device with dummy pads adjacent to contact pads and a method for forming the same. Contact pads can be contact pads in an integrated fan-out package, where the integrated fan-out package includes a molding compound located on the sidewalls of the die, and contact pads located on the die and the molding compound. The contact pads are electrically connected to the die using one or more redistribution layers. Dummy pad features are electrically insulated from the contact pads. In some embodiments, dummy pad features partially surround the contact pads and are located in corner regions of the molding compound, corner regions of the die, and/or interface regions between the die and the molding compound.

Despite the progress made by existing packaging technologies such as R.O.C. patents 111135356, 1671534, and U.S. Pat. No. 9,691,686B2 in their respective application fields, they still show significant limitations in improving the overall performance of chip packaging, particularly in terms of electrical connection stability and protection capabilities. These technologies fail to fully address the growing demand for high-performance and high-reliability in chip packaging, especially concerning stringent requirements for packaging protection (particularly oxidation resistance) and electrical connection stability in modern high-performance electronic devices.

Therefore, these limitations in existing technologies highlight the urgent need for developing a new type of chip packaging structure that can effectively improve electrical connection performance and stability while providing comprehensive chip protection, especially against oxidation. The present invention aims to address the issues unresolved by existing technologies by introducing innovative chip packaging structures and manufacturing methods, thereby providing a more reliable and efficient chip packaging solution for high-performance electronic devices.

### SUMMARY OF THE INVENTION

In view of the above problems, the present invention provides a semiconductor package structure with an improved die pad, aiming to solve many of the limitations in existing technologies, particularly regarding electrical connection stability, die pad protection effectiveness, and packaging structure reliability. Through a series of innovative structural designs and process technologies, the present invention enhances the overall performance and durability of chip packaging while ensuring high efficiency and cost-effectiveness.

Thus, the core of the present invention is the improved design of the die pad on the chip unit, where each die pad has a bonding area and a peripheral area, and introduces a nickel-gold layer directly covering the die pad. This design not only enhances the electrical connection between the die pad and the carrier board but also significantly improves the protection effect of the die pad through the excellent anti-oxidation characteristics of the nickel-gold layer, thereby extending the lifespan of the packaging structure.

Another objective of the present invention is to provide stable electrical connections between the chip unit and the carrier board by employing at least one connection technology, including but not limited to wire bonding, Redistribution Layer (RDL), or direct soldering. The selection and application of these technologies, combined with the protection of the nickel-gold layer, ensure high reliability and long-term stability of the connections, especially under demanding conditions such as high frequency, high speed, or high temperature.

Furthermore, the present invention provides different embodiments of packaging structures, including the comprehensive or partial coverage of the die pad with a nickel-gold layer, and selectively adding protective layers to enhance the protection of the peripheral area of the die pad. These embodiments demonstrate the advantage of the present invention in providing flexible packaging solutions that can be adjusted and optimized according to specific application requirements.

In summary, the improved die pad semiconductor package structure of the present invention effectively overcomes the limitations of prior technologies through its unique design and technical innovations, providing a more reliable, efficient, and economical packaging solution. This not only promotes advancements in packaging technology but also offers significant performance enhancements and cost advantages for a wide range of electronic device applications.

To achieve the above objectives, the primary technical means adopted by the present invention is implemented through the following technical scheme. The present invention is a semiconductor package structure with an improved die pad, comprising: a chip unit having a surface, with at least one die pad on the surface, each die pad having a bonding area and a peripheral area surrounding the bonding area; a nickel-gold layer directly covering at least one of the die pads; a carrier board equipped with multiple connection pads for electrical connection with the bonding area of at least one of the die pads; characterized in that at least one type of connection technology is used to achieve electrical connection between at least one of the die pads on the chip unit and at least one of the connection pads on the carrier board, ensuring a stable electrical connection state between the chip unit and the carrier board, where the at least one type of connection technology includes but is not limited to wire bonding, Redistribution Layer (RDL), or direct soldering.

The objectives and solutions of the present invention can also be further realized by the following technical measures.

The structure as described above, wherein the die pad, the nickel-gold layer, and a protective layer are sequentially stacked, with the protective layer located on the peripheral area of the die pad.

The structure as described above, wherein a protective layer is directly located on the peripheral area of the die pad.

The structure as described above, wherein at least one of the die pads is made of aluminum material.

The structure as described above, wherein at least one protective layer on the semiconductor package structure further covers part of the peripheral area of at least one of the die pads.

The structure as described above, wherein at least one protective layer on the semiconductor package structure further covers the peripheral area of all the die pads, and the protective layer fully covers the surface of the chip unit.

The structure as described above, wherein at least one protective layer on the semiconductor package structure covers only the peripheral area of one die pad.

Another method to achieve the above objectives of the present invention is implemented through the following technical scheme. A method for manufacturing a semiconductor package structure with an improved die pad, comprising the following steps: Step a: on the surface of a chip unit, setting at least one die pad through photolithography and etching processes, each die pad having a bonding area and a peripheral area surrounding the bonding area; Step b: forming a nickel-gold layer on at least one of the die pads through electroplating or chemical vapor deposition techniques to optimize electrical connection performance; Step c: implementing at least one type of connection technology to achieve electrical connection between at least one of the die pads on the chip unit and multiple connection pads on a carrier board, with the at least one type of connection technology selected from the following combinations: direct wire bonding, Redistribution Layer formation, direct soldering connection.

The method as described above, wherein after step a, at least one protective layer is formed on the peripheral area of at least one of the die pads by applying spin coating or chemical vapor deposition techniques.

Compared with prior art, the present invention provides an improved chip packaging structure that significantly enhances the electrical connection performance and stability between the chip and the carrier board by directly covering the die pad with a nickel-gold layer. This innovative covering method not only optimizes the quality of electrical connections but also enhances overall protection of the chip, particularly providing excellent anti-oxidation protection, thereby effectively extending the lifespan of the semiconductor package structure. Additionally, the advanced connection technologies adopted by the present invention, such as wire bonding, Redistribution Layer (RDL), or direct soldering, further improve the overall reliability and performance of the packaging structure.

The chip packaging solution of the present invention provides higher market competitiveness for high-performance electronic devices, enabling end products to meet more stringent performance requirements and longer service lifespans. Through the implementation of the present invention, manufacturers can produce highly reliable electronic components that meet current and future market demands, thereby maintaining a leading position in technological innovation and product quality.

### BRIEF DESCRIPTIONS OF THE DRAWINGS

FIG. 1 is a top view of the first preferred embodiment of the present invention, showing the layout of the chip unit and its die pads.

FIG. 2a is a top view of the second preferred embodiment of the present invention, showing the structure of the die pad directly covered with a nickel-gold layer.

FIG. 2b is a top view of the third preferred embodiment of the present invention, depicting the structure where the nickel-gold layer fully covers the die pad.

FIG. 2c is a top view of the fourth preferred embodiment of the present invention, showing the structure of the die pad where the nickel-gold layer covers the bonding area and the protective layer covers the peripheral area.

FIG. 3 is a cross-sectional view of the first preferred embodiment of the present invention, showing the basic cross-sectional structure of the chip unit and the die pad.

FIG. 4a is a cross-sectional view of the second preferred embodiment of the present invention, showing the nickel-gold layer and the protective layer in the chip packaging structure.

FIG. 4b is a cross-sectional view of the third preferred embodiment of the present invention, showing the nickel-gold layer and the protective layer in the chip packaging structure.

FIG. 4c is a cross-sectional view of the fourth preferred embodiment of the present invention, showing the nickel-gold layer and the protective layer in the chip packaging structure.

FIG. 4d is a cross-sectional view of the fifth preferred embodiment of the present invention, showing the nickel-gold layer and the protective layer in the chip packaging structure.

FIG. 5a is a top view of the sixth preferred embodiment of the present invention, showing the complete packaging structure where the electrical connection between the chip unit and the carrier board is achieved through solder wires.

FIG. 5b is a top view of the seventh preferred embodiment of the present invention, showing the complete chip packaging structure with a protective layer and the configuration of solder wire connections.

FIG. 6a is a cross-sectional view of the eighth preferred embodiment of the present invention, showing the position of the nickel-gold layer and the protective layer and their impact on electrical connections.

FIG. 6b is a cross-sectional view of the ninth preferred embodiment of the present invention, showing the position of the nickel-gold layer and the protective layer and their impact on electrical connections.

FIG. 6c is a cross-sectional view of the tenth preferred embodiment of the present invention, showing the position of the nickel-gold layer and the protective layer and their impact on electrical connections.

FIG. 6d is a cross-sectional view of the eleventh preferred embodiment of the present invention, showing the position of the nickel-gold layer and the protective layer and their impact on electrical connections.

FIG. 7a is a cross-sectional view of the twelfth preferred embodiment of the present invention, showing the chip packaging structure combined with Redistribution Layer (RDL) technology.

FIG. 7b is a cross-sectional view of the thirteenth preferred embodiment of the present invention, showing the chip packaging structure combined with solder ball technology.

FIG. 8a is the first process flow diagram of the preferred embodiment of the present invention.

FIG. 8b is the second process flow diagram of the preferred embodiment of the present invention.

### DETAILED DESCRIPTIONS OF THE PREFERRED EMBODIMENTS

To better understand the objectives, features, and effects of the present invention, the following specific embodiments are provided:

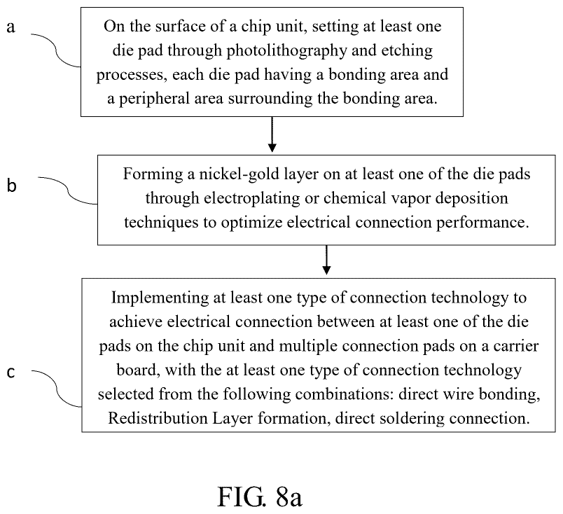

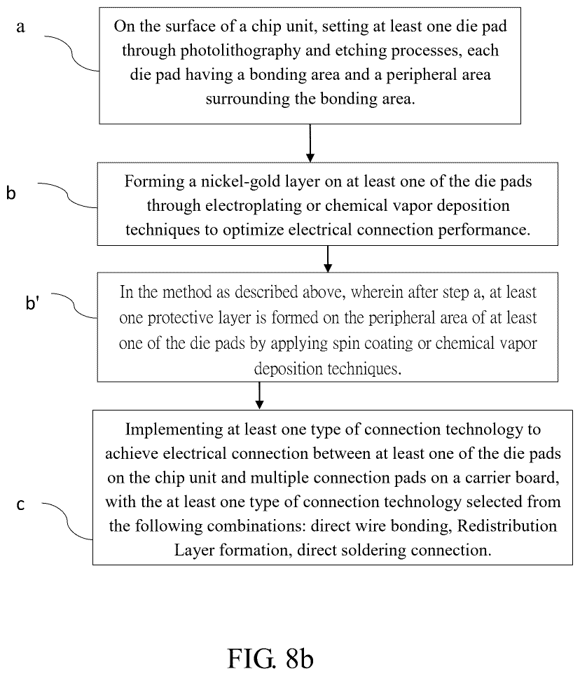

First, the first embodiment of the semiconductor package structure and its manufacturing method of the present invention is introduced: Please refer to the flowchart in FIG. 8a, which mainly consists of steps a (a), b (b), and c (c). FIG. 8a shows the overall manufacturing process of the first embodiment, with step a (a) involving the setting of the die pad, step b (b) involving the formation of the nickel-gold layer, and step c (c) involving the implementation of the electrical connection. Each step is precisely executed to ensure the packaging structure achieves optimal performance and reliability.

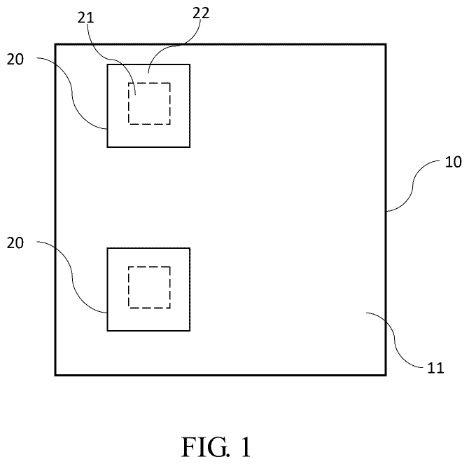

As shown in FIG. 1, this embodiment starts with the preparation of the chip unit (10), with at least one die pad (20) set on the surface (11) of the chip unit. The die pad (20) includes a bonding area (21) and a peripheral area (22). This step is completed through precise photolithography and etching processes, providing accurate positioning and structural basis for the subsequent nickel-gold layer coverage.

In most applications, the design of the die pad (20) is flush with or slightly protruding from the surface (11) of the chip unit, without requiring special grooves. However, for specific applications requiring high-density packaging or minimizing space between the chip and the package, special groove designs may be adopted. Such designs better protect the die pad (20) from mechanical stress while allowing more chip components to be integrated within limited space.

In some high-precision applications of the present invention, the die pad (20) may further adopt microgroove technology, which allows more precise positioning and protection of connection materials, such as gold wires or micro solder balls. This technology not only enhances the overall performance of the package but also increases the reliability of the structure under extreme operating conditions.

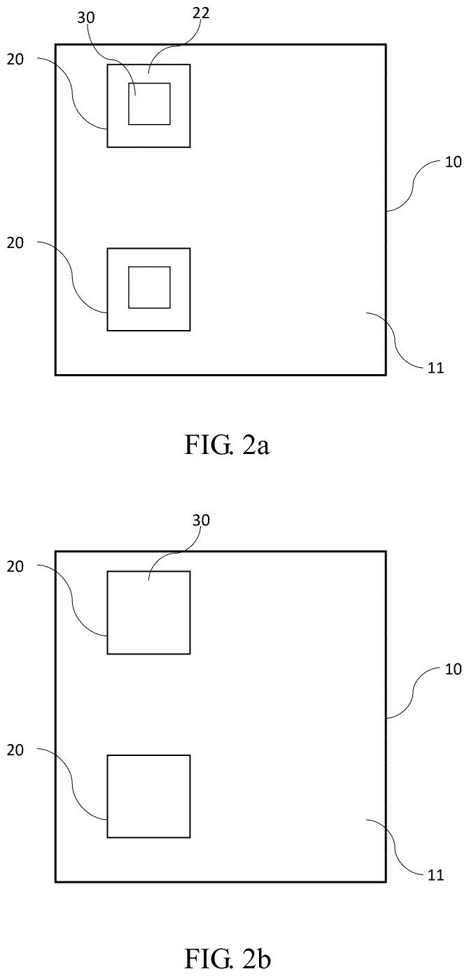

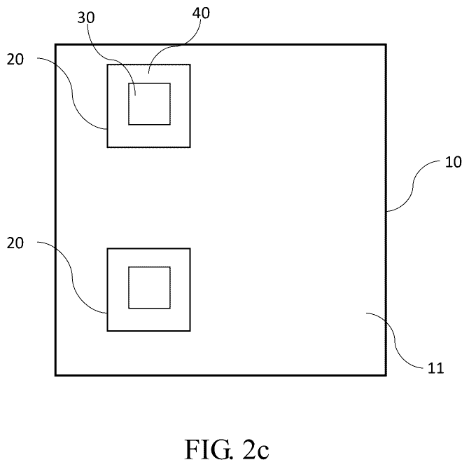

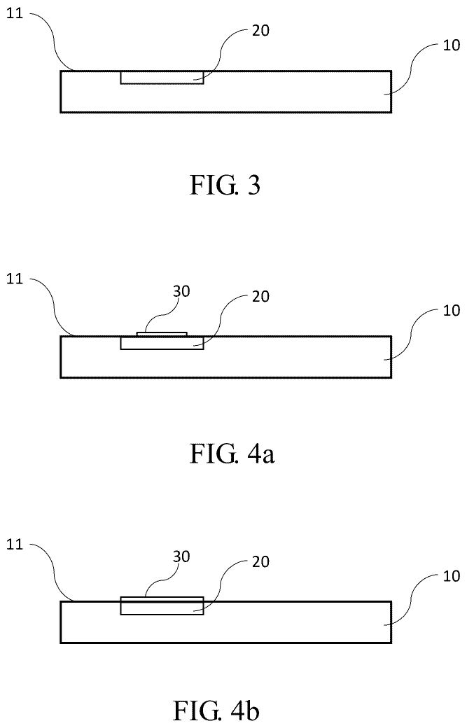

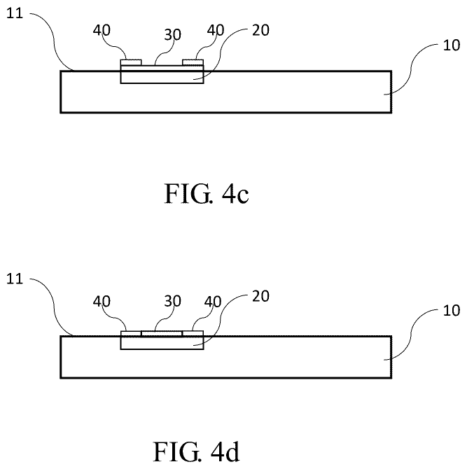

As shown in FIG. 2a and FIG. 4a, electroplating or chemical vapor deposition (CVD) techniques are used to directly form a nickel-gold layer (30) on the bonding area (21) of the die pad. The main function of this layer is to provide optimized electrical connection and oxidation protection, ensuring the reliability and long lifespan of the chip during use.

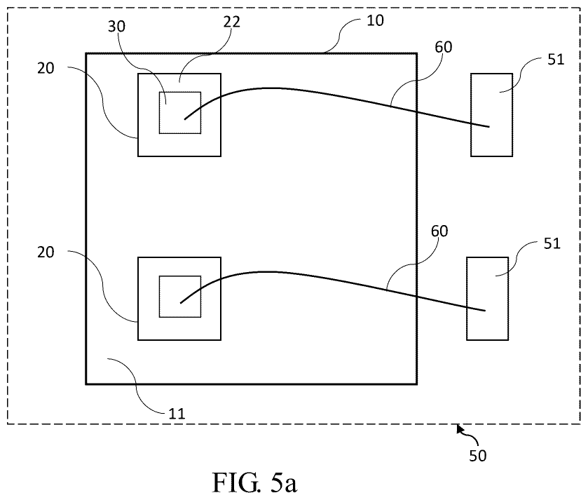

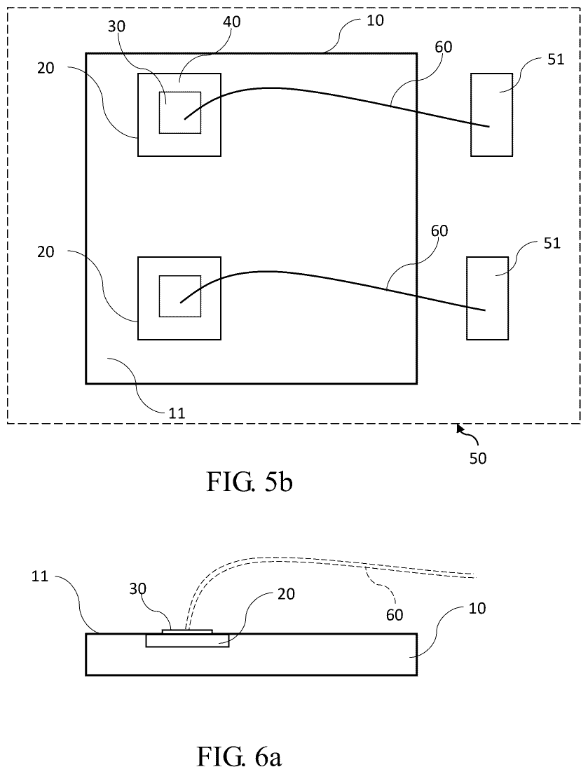

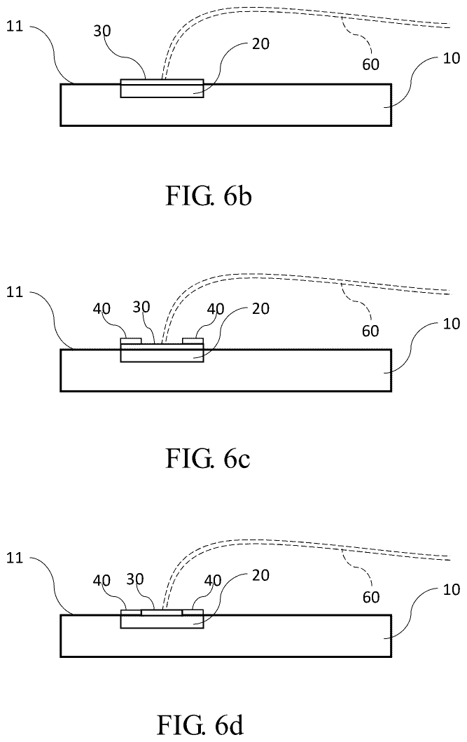

Finally, as shown in FIG. 5a and FIG. 6a, direct wire bonding technology is used to establish electrical connections between the chip unit and the carrier board (50). After being protected by the nickel-gold layer (30), the bonding area (21) of the die pad (20) remains exposed to facilitate the connection, ensuring good electrical connection while maintaining protection of the bonding area.

Specifically, the chip unit (10) is the core of the packaging structure of the present invention, containing the semiconductor chip that needs to be packaged and protected. The surface (11) of the chip unit (10) provides the base for subsequent die pad settings and metal layer coverage, serving as a critical part for realizing the functions of electronic devices. The surface (11) refers to the area on the chip unit (10) used for installing the die pad (20). This surface is finely processed to ensure suitable flatness and cleanliness for subsequent die pad settings and metal layer coverage. The die pad (20) acts as a crucial interface for electrical connections, directly installed on the surface (11) of the chip unit, and can be made of aluminum material. Each die pad comprises two main parts: the bonding area (21) and the peripheral area (22), where the bonding area is the place for electrical connections with external connection pads or wires. The bonding area (21) is located in the central part of the die pad (20), being a key area for achieving electrical connections between the chip and the carrier board (50). The design and material selection of the bonding area are crucial for ensuring the stability and efficiency of electrical connections. The peripheral area (22) surrounds the bonding area (21), providing additional structural support and helping to protect the bonding area from physical damage. In some embodiments, the peripheral area is also used to place protective layers, enhancing the overall protection of the packaging structure. The nickel-gold layer (30) directly covers the bonding area (21) of the die pad, providing excellent electrical conductivity and protection, especially against oxidation. The introduction of this layer significantly improves the overall performance of the chip package, particularly in terms of electrical connection performance and stability. The manufacturing method described in this embodiment can effectively enhance the electrical connection performance and stability of the semiconductor package structure while significantly improving the protection of the chip, especially against oxidation. This improved die pad semiconductor package structure and its manufacturing method provide a high-performance, high-reliability chip packaging solution for modern high-performance electronic devices.

Next, the second embodiment of the semiconductor package structure and its manufacturing method of the present invention is introduced: Please refer to the flowchart in FIG. 8a, which mainly consists of steps a (a), b (b), and c (c). FIG. 8a shows the overall manufacturing process of the second embodiment, with step a (a) involving the setting of the die pad, step b (b) involving the comprehensive coverage of the nickel-gold layer, and step c (c) involving the implementation of the electrical connection. Each step is precisely executed to ensure the packaging structure achieves optimal performance and reliability.

As shown in FIG. 1, this embodiment starts with the preparation of the chip unit (10), with at least one die pad (20) set on the surface (11) of the chip unit. The die pad (20) includes a bonding area (21) and a peripheral area (22). This step utilizes precise photolithography and etching processes to ensure the correct formation of the die pad.

Next, as shown in FIG. 2b, FIG. 4b, and FIG. 6b, electroplating or chemical vapor deposition (CVD) techniques are used to form a nickel-gold layer (30) over the entire die pad (20), including the bonding area (21) and the peripheral area (22). This comprehensive coverage strategy aims to provide more extensive protection, especially against oxidation and other environmental factors, while maintaining good electrical connection performance.

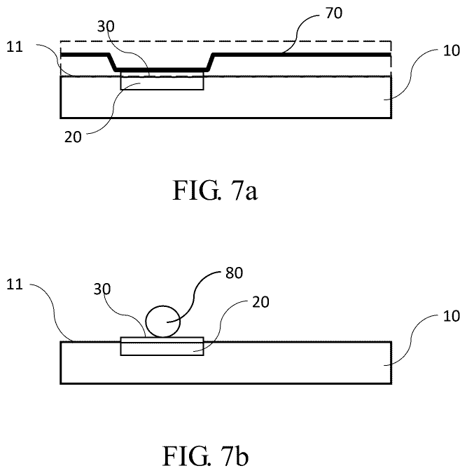

Finally, depending on the specific requirements of the chip packaging structure, suitable electrical connection technologies are selected. FIG. 6b illustrates the application of direct wire bonding technology; FIG. 7a shows the chip packaging structure using Redistribution Layer (RDL) technology to form the redistribution layer structure (70); and FIG. 7b displays the packaging structure using solder ball structure (80). These diversified connection technologies provide flexible solutions to meet different application scenarios' needs, enhancing connection reliability and the overall performance of the packaging.

In practice, the components identical to those in the first embodiment will not be reiterated. The die pad (20) is located on the surface (11) of the chip unit (10) and is a crucial interface for electrical connections between the chip's internal circuit and the external carrier board. In this embodiment, the entire surface of the die pad (20), including the bonding area (21) and the peripheral area (22), is covered by the nickel-gold layer (30). This comprehensive coverage design enhances the electrical connection performance and stability of the chip package while providing strong anti-oxidation protection. The carrier board (50) provides physical support for the chip unit and contains multiple connection pads (51). These connection pads (51) are used to form electrical connections with the die pads (20) on the chip unit (10). In this embodiment, the carrier board (50) serves as a bridge for connecting the chip to external circuits. The connection pads (51) located on the carrier board (50) are critical points for electrical connections between the carrier board (50) and the chip unit (10). The solder wire (60) is a fine metal wire used to establish electrical connections between the chip unit (10) and the carrier board (50). During the packaging process, the solder wire (60) connects the bonding area (21) on the chip to the connection pads (51) on the carrier board through welding technology, forming a stable electrical path. The solder wire not only provides a channel for electrical signal transmission but also plays a mechanical support role, ensuring the stability and reliability of the connection between the chip and the carrier board. The Redistribution Layer structure (70) is a fine conductive path formed on the surface of the chip or package, used to reconfigure the electrical connection points on the chip to align them with the connection pads (51) on the carrier board. It allows more flexible packaging design and can effectively solve wiring challenges in high-density packaging, enhancing the overall performance of the package and reducing package size. The solder ball structure (80) is a common connection element in Ball Grid Array (BGA) packages, consisting of tiny solder balls used to form physical and electrical connections between the chip unit (10) and the carrier board (50). The solder balls provide a high-density connection solution, allowing a large number of input/output connections while maintaining package miniaturization. This connection structure is widely used in high-density packaging designs due to its excellent electrical performance and mechanical stability.

Next, the third embodiment of the semiconductor package structure and its manufacturing method of the present invention is introduced: Please refer to the flowchart in FIG. 8b, which mainly consists of steps a (a), b (b), b′ (b′), and c (c). FIG. 8b shows the overall manufacturing process of the third embodiment, with step a (a) involving the setting of the die pad, step b (b) involving the coverage of the nickel-gold layer, step b′ (b′) involving the formation of the protective layer, and step c (c) involving the implementation of the electrical connection. Each step is precisely executed to ensure the packaging structure achieves optimal performance and reliability.

As shown in FIG. 1, this embodiment starts with the preparation of the chip unit (10), with at least one die pad (20) set on the surface (11) of the chip unit. The die pad (20) includes a bonding area (21) and a peripheral area (22). This step utilizes precise photolithography and etching processes to ensure the correct formation of the die pad.

As shown in FIG. 2c, a nickel-gold layer (30) is directly formed on the bonding area (21) and peripheral area (22) of the die pad. This step adopts electroplating or chemical vapor deposition (CVD) techniques. The addition of the nickel-gold layer not only optimizes electrical connection performance but also provides strong oxidation protection.

After the formation of the nickel-gold layer, as shown in FIG. 2c and FIG. 4c, a protective layer (40) is formed on the nickel-gold layer (30) of the peripheral area (22) of the die pad using spin coating or chemical vapor deposition (CVD) techniques. This protective layer (40) helps reduce the exposed area of the die pad (20), providing additional physical protection to the peripheral area of the die pad, reducing potential damage from environmental factors.

Finally, as shown in FIG. 5b and FIG. 6c, suitable electrical connection technology (direct wire bonding, Redistribution Layer structure, or solder balls, etc.) is used to achieve electrical connections between the chip unit and the carrier board (50). This step ensures that the electrical connections of the chip package structure are not only stable and reliable but also maintain high performance.

In general, the bonding area (21) on the die pad (20) is the key area directly used for electrical connections with the connection pads (51) on the carrier board. In this embodiment, the bonding area is covered by the nickel-gold layer (30) to enhance connection stability and oxidation resistance. The peripheral area (22) surrounds the bonding area (21), providing additional physical support. In this embodiment, the peripheral area (22) is also covered by the nickel-gold layer (30) and further formed with a protective layer (40) to enhance the overall protection of the packaging structure. The protective layer (40) is an additional protective layer formed on the nickel-gold layer (30) of the peripheral area (22), aimed at providing stronger physical and chemical protection, especially against environmental factors such as moisture and contaminants. The protective layer (40) is formed using spin coating or chemical vapor deposition (CVD) techniques.

Finally, the fourth embodiment of the semiconductor package structure and its manufacturing method of the present invention is introduced: Please refer to the flowchart in FIG. 8b, which mainly consists of steps a (a), b (b), b′ (b′), and c (c). FIG. 8b shows the overall manufacturing process of the third embodiment, with step a (a) involving the setting of the die pad, step b (b) involving the coverage of the nickel-gold layer, step b′ (b′) involving the formation of the protective layer, and step c (c) involving the implementation of the electrical connection. From the setting of the die pad to the formation of the nickel-gold layer and protective layer, and finally to the completion of the electrical connection, each step is precisely executed to ensure the performance and reliability of the packaging structure reach the optimal state.

As shown in FIG. 1, the manufacturing of the chip package starts with the preparation of the chip unit (10), where the surface (11) of the chip unit is configured with the die pad (20), including the bonding area (21) and the peripheral area (22). This step uses precise photolithography and etching techniques to form the die pad, providing the foundation for subsequent metal layer coverage.

As shown in FIG. 1, first, set the die pad (20) on the surface (11) of the chip unit (10), including the bonding area (21) and the peripheral area (22). The structure of the die pad is precisely formed through photolithography and etching processes to ensure the accurate execution of subsequent covering processes.

Next, as shown in FIG. 2c, using electroplating or chemical vapor deposition (CVD) techniques, a nickel-gold layer (30) is directly formed on the bonding area (21) of the die pad. This step focuses on covering the bonding area, aiming to optimize the electrical connection performance and protection of the area.

Subsequently, as shown in FIG. 2c and FIG. 4d, step b′ involves forming a protective layer (40) on the nickel-gold layer (30) of the peripheral area (22) of the die pad. This protective layer is achieved through spin coating or chemical vapor deposition (CVD) techniques, aimed at providing additional physical and chemical protection, particularly for the peripheral area of the die pad, enhancing the barrier against environmental factors.

Finally, as shown in FIG. 5b and FIG. 6d, suitable connection technology (such as direct wire bonding, Redistribution Layer structure, or solder balls) is used to achieve electrical connections between the chip unit and the carrier board (50). In this embodiment, the nickel-gold layer (30) on the bonding area (21) provides excellent electrical connection performance and stability, while the protective layer (40) on the peripheral area (22) further enhances the overall protection of the packaging structure.

Thus, the effectiveness of the present invention differs from general improved chip packaging structures. This is pioneering in the manufacturing process of die pads, meeting the requirements for an invention patent. Therefore, this application is filed with due documentation.

It should be reiterated that the above descriptions are merely preferred embodiments of the present invention. Any equivalent changes made based on the description, claims, or drawings of the present invention are still within the technical scope protected by the present invention. Therefore, the protection scope of the present invention should be defined by the appended claims.

What is claimed is:

1. A semiconductor package structure with improved die pad, comprising:
a chip unit having a surface, with at least one die pad on the surface, each die pad having a bonding area and a peripheral area surrounding the bonding area;
a nickel-gold layer directly covering at least one of the die pads;
a carrier board equipped with multiple connection pads for electrical connection with the bonding area of at least one of the die pads;
characterized in that at least one type of connection technology is used to achieve electrical connection between at least one of the die pads on the chip unit and at least one of the connection pads on the carrier board, ensuring a stable electrical connection state between the chip unit and the carrier board, where the at least one type of connection technology includes but is not limited to wire bonding, redistribution layer (RDL), or direct soldering.

2. The semiconductor package structure with improved die pad as claimed in claim 1, wherein the die pad, the nickel-gold layer, and a protective layer are sequentially stacked, with the protective layer located on the peripheral area of the die pad.

3. The semiconductor package structure with improved die pad as claimed in claim 1, wherein a protective layer is directly located on the peripheral area of the die pad.

4. The semiconductor package structure with improved die pad as claimed in claim 1, wherein at least one of the die pads is made of aluminum material.

5. The semiconductor package structure with improved die pad as claimed in claim 1, wherein at least one protective layer on the semiconductor package structure further covers part of the peripheral area of at least one of the die pads.

6. The semiconductor package structure with improved die pad as claimed in claim 1, wherein at least one protective layer on the semiconductor package structure further covers part of the peripheral area of at least one of the die pads.

7. The semiconductor package structure with improved die pad as claimed in claim 1, wherein at least one protective layer on the semiconductor package structure covers only the peripheral area of one die pad.

8. A method for manufacturing a semiconductor package structure with improved die pad, comprising the following steps:
Step a: on the surface of a chip unit, setting at least one die pad through photolithography and etching processes, each die pad having a bonding area and a peripheral area surrounding the bonding area;
Step b: forming a nickel-gold layer on at least one of the die pads through electroplating or chemical vapor deposition techniques to optimize electrical connection performance;
Step c: implementing at least one type of connection technology to achieve electrical connection between at least one of the die pads on the chip unit and multiple connection pads on a carrier board, with the at least one type of connection technology selected from the following combinations: direct wire bonding, redistribution layer formation, direct soldering connection.

9. The method for manufacturing a semiconductor package structure with improved die pad as claimed in claim 8, wherein after step a, at least one protective layer is formed on the peripheral area of at least one of the die pads by applying spin coating or chemical vapor deposition techniques.
